(19) United States
(12) Patent Application Publication
(10) Pub. No.: US 2011/0198689 A1
(43) Pub. Date: Aug. 18, 2011

(54) SEMICONDUCTOR DEVICES CONTAINING TRENCH MOSFETS WITH SUPERJUNCTIONS

(76) Inventor: Suku Kim, South Jordan, UT (US)

(21) Appl. No.: 12/707,323

(22) Filed: Feb. 17, 2010

(51) Int. Cl. H01L 29/78

(52) U.S. Cl. 257/331; 257/E29.262; 257/E29.257

(57) ABSTRACT

Semiconductor devices combining a MOSFET architecture with a PN super-junction structure and methods for making such devices are described. The MOSFET architecture can be made using a trench configuration containing a gate that is sandwiched between thick dielectric layers in the top and the bottom of the trench. The PN junction of the super-junction structure is formed between n-type dopant regions in the sidewalls of the trench and a p-type epitaxial layer. The gate of the trench MOSFET is separated from the super-junction structure using a gate insulating layer. Such semiconductor devices can have a lower capacitance and a higher breakdown voltage relative to shield-based trench MOSFET devices and can replace such devices in medium to high voltage ranges. Other embodiments are described.

### FIELD

This application relates generally to semiconductor devices and methods for making such devices. More specifically, this application describes semiconductor devices combining a MOSFET architecture with a PN super-junction structure and methods for making such devices.

### BACKGROUND

Semiconductor devices containing integrated circuits (ICs) or discrete devices are used in a wide variety of electronic apparatus. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning. Silicon wafers are typically used as the substrate and photolithography is used to mark different areas of the substrate to be doped or to deposit and define polysilicon, insulators, or metal layers.

One type of semiconductor device, a metal oxide silicon field effect transistor (MOSFET) device, can be widely used in numerous electronic apparatus, including automotive electronics, disk drives and power supplies. Generally, these devices function as switches, and they are used to connect a power supply to a load. Some MOSFET devices can be formed in a trench that has been created in a substrate. One feature making the trench configuration attractive is that the current flows vertically through the channel of the MOSFET. This permits a higher cell and/or current channel densities than other MOSFETs where the current flows horizontally through the channel and then vertically through the drain. Greater cell and/or current channel densities generally mean more MOSFETs and/or current channels can be manufactured per unit area of the substrate, thereby increasing the current density of the semiconductor device containing the trench MOSFET.

### SUMMARY

This application describes semiconductor devices combining a MOSFET architecture with a PN super-junction structure and methods for making such devices. The MOSFET architecture can be made using a trench configuration containing a gate that is sandwiched between thick dielectric layers in the top and the bottom of the trench. The PN junction of the super-junction structure is formed between n-type dopant regions in the sidewalls of the trench and a p-type epitaxial layer for N-channel MOSFET. The dopant types can be reversed for P-channel MOSFET. The gate of the trench MOSFET is separated from the super-junction structure using insulating layers. Such semiconductor devices can have a lower capacitance and a higher breakdown voltage relative to shield-based trench MOSFET devices and can replace such devices in medium voltage ranges.

### BRIEF DESCRIPTION OF THE DRAWINGS

The following description can be better understood in light of the Figures, in which:

FIG. 1 shows some embodiments of methods for making a semiconductor structure containing a substrate and an epitaxial (or “epi”) layer with a mask on the upper surface of the epitaxial layer;

FIG. 2 depicts some embodiments of methods for making a semiconductor structure containing a trench structure formed in the epitaxial layer;

FIG. 3 shows some embodiments of methods for making a semiconductor structure with a first oxide region formed in the trench;

FIGS. 4a and 4b depict some embodiments of methods for making a semiconductor structure with a gate and a gate insulator formed in the trench;

FIGS. 5a and 5b shows some embodiments of methods for making a semiconductor structure with an insulation cap formed over the gate in the trench and a contact region formed in the epitaxial layer;

FIG. 6 shows some embodiments of methods for making a semiconductor structure with a source formed over the insulation cap and the contact region;

FIG. 7 shows some embodiments of methods for making a semiconductor structure with a drain formed on the bottom of the structure;

FIG. 8 shows some embodiments of the operation of the semiconductor structure depicted in FIG. 7; and

FIGS. 9 and 10 show some embodiments of the PN junctions that can be present in semiconductor structures.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while description refers to trench MOSFET devices, it could be modified for other semiconductor devices formed in trenches, such as Static Induction Transistor (SIT), Static Induction Thyristor (SITh), JFET, and thyristor devices. As well, although the devices are described with reference to a particular type of conductivity (P or N), the devices can be configured with a combination of the same type of dopant or can be configured with the opposite type of conductivity (N or P, respectively) by appropriate modifications.

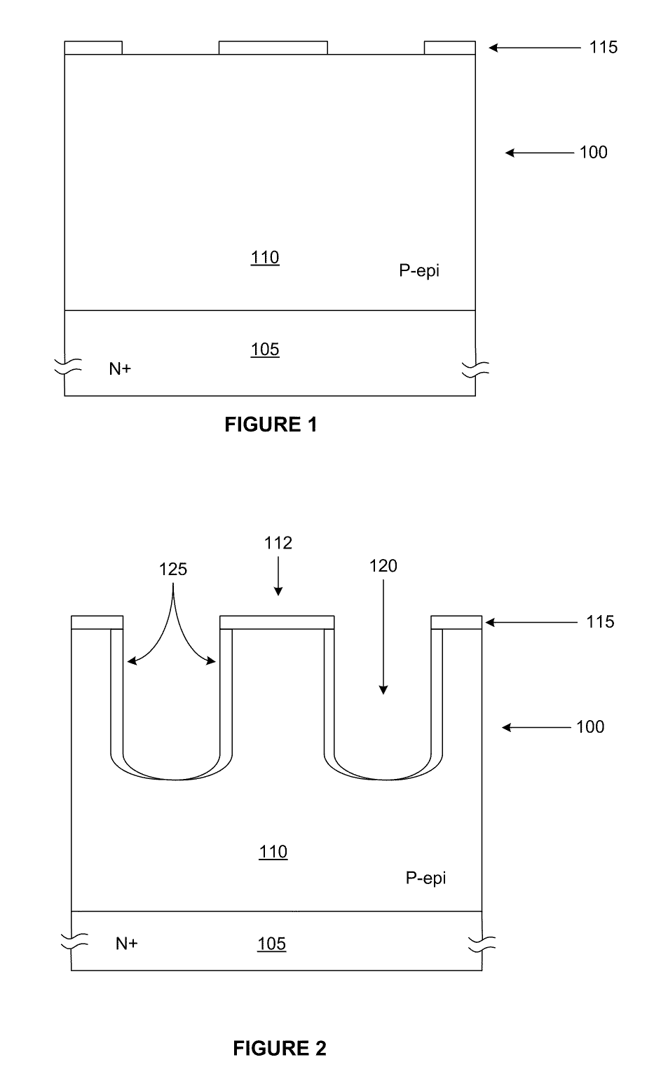

Some embodiments of the semiconductor devices and methods for making such devices are shown in FIGS. 1-10. The methods begin in some embodiments, as depicted in FIG. 1, when a semiconductor substrate 105 is first provided. Any substrate known in the art can be used in the invention. Suitable substrates include silicon wafers, epitaxial Si layers, bonded wafers such as used in silicon-on-insulator (SOI) technologies, and/or amorphous silicon layers, all of which may be doped or undoped. Also, any other semiconducting material used for electronic devices can be used, including Ge, SiGe, SiC, GaN, GaAs, InₓGa_{y}As_{z}, AlₓGa_{y}As_{z}, and/or any pure or compound semiconductors, such as III-V or II-VIs and their variants. In some embodiments, the substrate 105 can be heavily doped with any n-type dopant.

In some embodiments, the substrate 105 contains one or more epitaxial (“epi”) Si layers (individually or collectively depicted as epitaxial layer 110) located on an upper surface thereof. For example, a lightly doped N epi layer can exist between substrate 105 and epitaxial layer 110. The epitaxial layer(s) 110 can be provided using any known process in the art, including any known epitaxial deposition process. The epitaxial layer(s) can be lightly doped with a p-type dopant.

In some configurations, the dopant concentration within the epitaxial layer 110 is not uniform. In particular, the epitaxial layer 110 can have a higher dopant concentration in an upper portion and a lower dopant concentration in a lower portion. In some embodiments, the epitaxial layer can have a concentration gradient throughout its depth with a higher concentration near or at the upper surface and a lower concentration near or at the interface with the substrate 105. The concentration gradient along the length of the epitaxial layer can be a consistent decrease, a step-wise decrease, or a combination thereof.

In some configurations to obtain this concentration gradient, multiple epitaxial layers can be provided on the substrate 105 and each epitaxial layer can contain a different dopant concentration. The number of epitaxial layers can range from 2 to as many as needed. In these configurations, each successive epitaxial layer is deposited on the underlying epitaxial layer (or substrate) while being in-situ doped to a higher concentration by any known method for epitaxial layer growth. One example of epitaxial layers 110 includes a first epitaxial Si layer with a first concentration, a second epitaxial Si layer with a higher concentration, a third epitaxial Si layer with an even higher concentration, and a fourth epitaxial Si layer with the highest concentration.

Next, as shown in FIG. 2, a trench structure 120 can be formed in the epitaxial layer 110, and the bottom of the trench can reach anywhere in epitaxial layer 110 or substrate 105. The trench structure 120 can be formed by any known process. In some embodiments, a mask 115 can be formed on the upper surface of the epitaxial layer 110. The mask 115 can be formed by first depositing a layer of the desired mask material and then patterning it using photolithography and etch process so the desired pattern for the mask 115 is formed. After the etching process used to create the trench is complete, a mesa structure 112 has been formed between adjacent trenches 120.

The epitaxial layer 110 can then be etched by any known process until the trench 120 has reached the desired depth and width in the epitaxial layer 110. The depth and width of the trench 120, as well as the aspect ratio of the width to the depth, can be controlled so that so a later deposited oxide layer properly fills in the trench and avoids the formation of voids. In some embodiments, the depth of the trench can range from about 0.1 to about 100 μm. In some embodiments, the width of the trench can range from about 0.1 to about 50 μm. With such depths and widths, the aspect ratio of the trench can range from about 1:1 to about 1:50. In other embodiments, the aspect ratio of the trench can range from about 1:5 to about 1:8.3.

In some embodiments, the sidewall of the trench is not perpendicular to the upper surface of the epitaxial layer 110. Instead, the angle of the trench sidewall can range from about 90 degrees (a vertical sidewall) to about 60 degrees relative to the upper surface of the epitaxial layer 110. The trench angle can be controlled so a later deposited oxide layer or any other material properly fills in the trench and avoids the formation of voids.

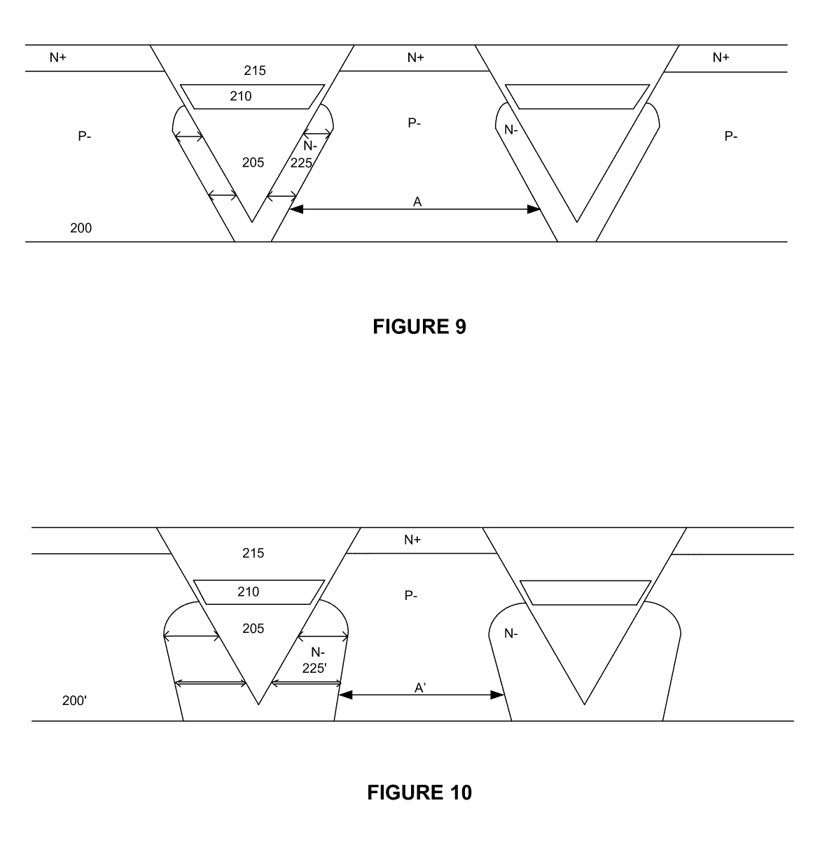

Next, as shown in FIG. 2, the sidewall of the trench structure 120 can be doped with an n-type dopant so that a sidewall dopant region 125 is formed in the epitaxial layer near the sidewall of the trench. The sidewall doping process can be performed using any doping process which implants the n-type dopants to the desired width. After the doping process, the dopants can be further diffused by any known diffusion or drive-in process. The width of the sidewall dopant region 125 can be adjusted so that the mesa 112 adjacent to any trench can be partially or fully depleted when the semiconductor device is off and the current is blocked (as depicted in FIG. 8). In some embodiments, this sidewall doping process can be performed using any angled implant process, a gas phase doping process, a diffusion process, depositing doped materials (poly silicon, BPSG, etc) and drive the dopants into the side wall, or a combination thereof. In other embodiments, an angled implantation process can be used with an angle ranging from about 0 degrees (a vertical implant process) to about 45 degrees, as shown by arrows 113. In some configurations, the width of the mesas 112, the depth of the trenches 120, the implantation angle, and the angle of the trench sidewall can be used to determine the width and depth of the n-type doped region 125 of the side wall. Accordingly, in these configurations, where the depth of the trenches range from about 0.1 to about 100 μm and the angle of the trench sidewall range from about 70 to about 90 degrees, the width of the mesas can range from about 0.1 to about 100 μm.

Where the trench has a sidewall angle as described herein, the different dopant concentrations in the epitaxial layers 110 help form a PN super-junction structure with a well defined PN junction. With this sidewall angle, the width of the trench decreases slightly as the depth of the trench increases. When the angled implant process is performed on such a sidewall, the n-type sidewall dopant region created in the p-type epitaxial layer 110 will have a substantially similar angle. But the resulting structure at the PN junction contains a p-type region that is relatively larger than the n-type region, which can detract from the performance of the PN super-junction since it may not be charge balanced. By modifying the dopant concentration in the epitaxial layer 110 as described above and increasing the dopant concentration from the bottom to the top of the device, the angled implant process creates a substantially straighter PN junction rather than an angled PN junction, as shown in FIGS. 9 and 10. FIG. 9 illustrates a semiconductor structure containing n-regions 225, an angled trench 205, gate 210, insulating layer 215, and epitaxial layer 200 that contains a uniform dopant concentration. The n-regions 225 from one trench to another are separated by distance A in the P⁻ region of the epitaxial layer. The distance A, however, is wider than is needed for proper charge balance and depletion. On the other hand, the semiconductor structure depicted in FIG. 10 contains a similar structure, but the epitaxial layer 200′ contains the gradient dopant concentration described herein. This gradient concentration allows the formation and adjustment of n-region 225′ that has a wider bottom, making the distance A′ between the n-regions 225′ smaller than A. The result of this configuration allows a more change-balanced semiconductor structure relative to the structure in FIG. 9.

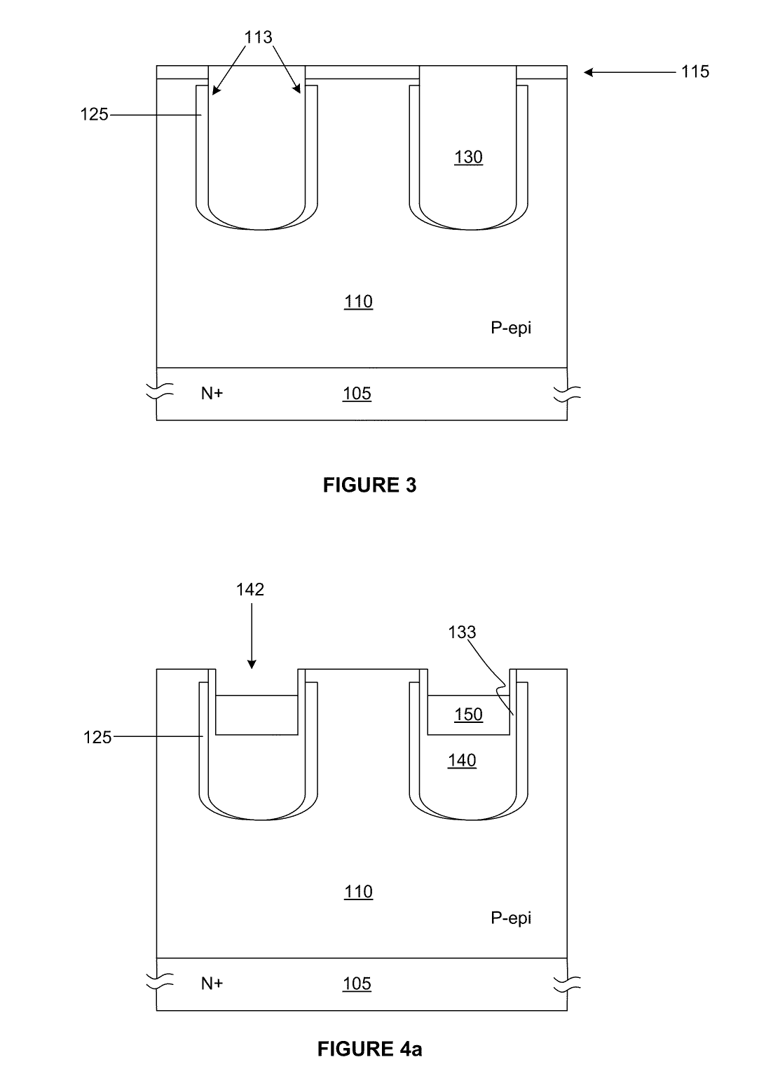

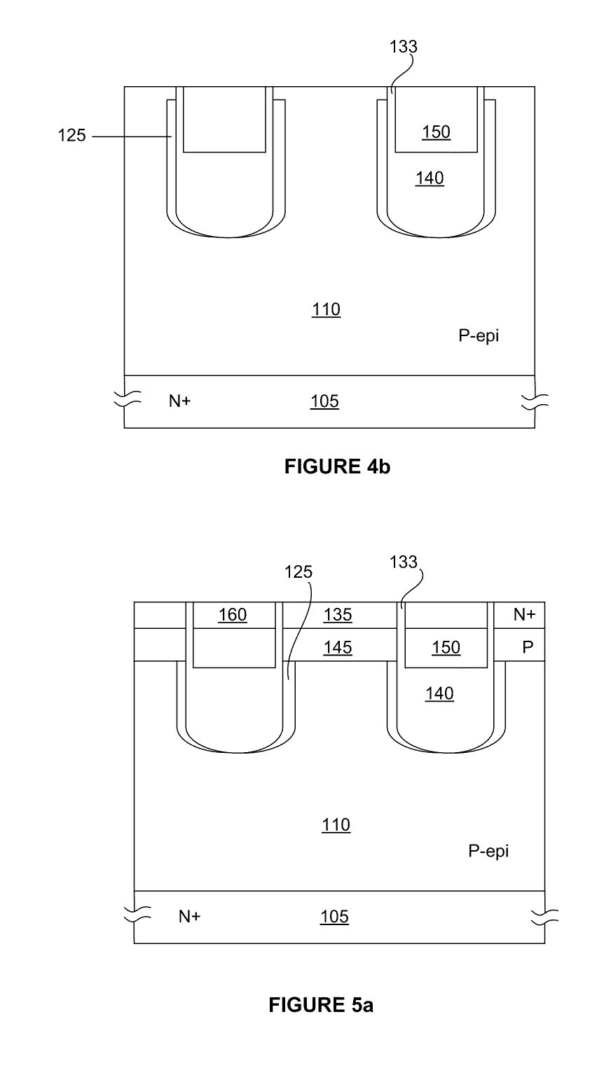

Returning to FIG. 3, an oxide layer 130 (or other insulating or semi-insulating material) can then be formed in the trenches 120. The oxide layer 130 can be formed by any process known in the art. In some embodiments, the oxide layer 130 can be formed by depositing an oxide material until it overflows the trenches 120. The thickness of the oxide layer 130 can be adjusted to any thickness needed to fill the trench 120. The deposition of the oxide material can be carried out using any known deposition process, including any chemical vapor deposition (CVD) processes, such as SACVD which can produce a highly conformal step coverage within the trench. If needed, a reflow process can be used to reflow the oxide material, which will help reduce voids or defects within the oxide layer. After the oxide layer 130 has been deposited, an etchback process can be used to remove the excess oxide material. After the etchback process, an oxide region 140 is formed in the bottom of the trench 120, as shown in FIGS. 4a and 4b. A planarization process, such as any chemical and/or mechanical polishing known in the art, can be used in addition to (whether before or after) or instead of the etchback process.

Optionally, a high quality oxide layer can be formed prior to depositing the oxide layer 130. In these embodiments, the high quality oxide layer can be formed by oxidizing the epitaxial layer 110 in an oxide-containing atmosphere until the desired thickness of the high-quality oxide layer has been grown. The high quality oxide layer can be used to improve the oxide integrity and filling factor, thereby making the oxide layer 130 a better insulator.

After formation of the bottom oxide region 140, a gate insulating layer (such as a gate oxide layer 133) is grown on the exposed sidewalls of the trench 120 that are not covered by the bottom oxide layer 140, as shown in FIG. 4. The gate oxide layer 133 can be formed by any process which oxidizes the exposed silicon in the sidewalls of the trench until the desired thickness is grown.

Subsequently, a conductive layer can be deposited on the bottom oxide region 140 in the lower, middle, or upper part of the trench 120. The conductive layer can comprise any conductive and/or semiconductive material known in the art including any metal, silicide, semiconducting material, doped polysilicon, or combinations thereof. The conductive layer can be deposited by any known deposition process, including chemical vapor deposition processes (CVD, PECVD, LPCVD) or sputtering processes using the desired metal as the sputtering target.

The conductive layer can be deposited so that it fills and overflows over the upper part of the trench 120. Then, a gate 150 can be formed from the conductive layer using any process known in the art. In some embodiments, the gate 150 can be formed by removing the upper portion of the conductive layer using any process known the art, including any etchback process. The result of the removal process leaves a conductive layer (the gate 150) overlying the first oxide region 140 in the trench 120 and sandwiched between the gate oxide layers 133, as shown in FIG. 4a. In some embodiments, a gate 155 can be formed so that its upper surface is substantially planar with the upper surface of the epitaxial layer 110, as shown in FIG. 4b.

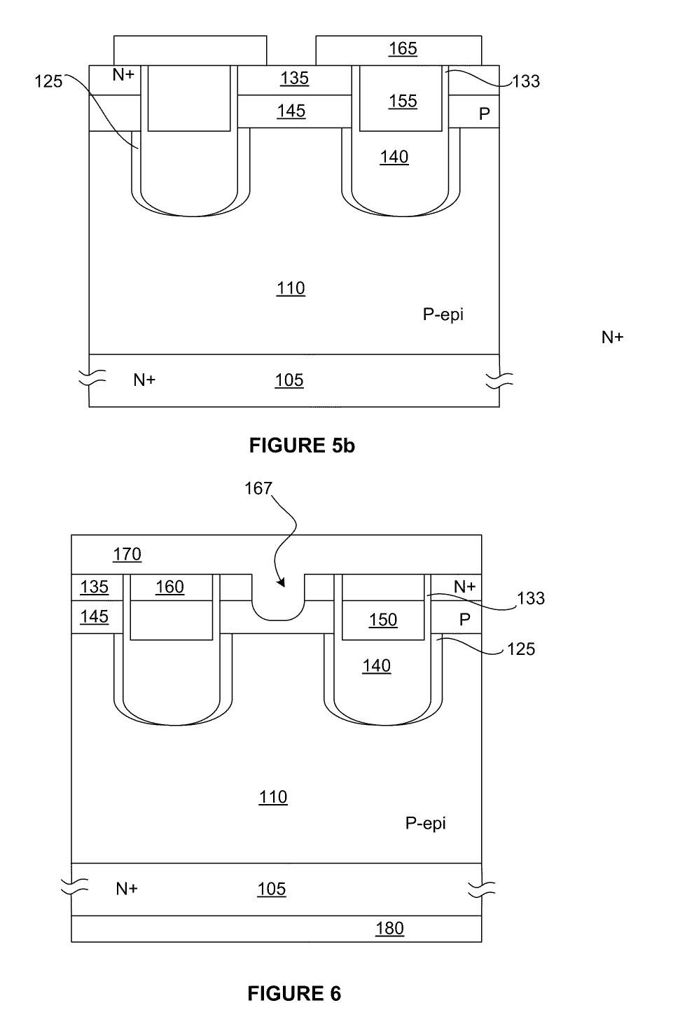

Then, a p-region 145 can be formed in an upper portion of the epitaxial layer 110, as shown in FIGS. 5a and 5b. The p-region can be formed using any process known in the art. In some embodiments, the p-regions regions 145 can be formed by implanting a p-type dopant in the upper surface of the epitaxial layer 110 and then driving-in the dopant using any known process.

Next, a contact region 135 can be formed on the exposed upper surface of the epitaxial layer 110. The contact region 135 can be formed using any process known in the art. In some embodiments, the contact regions 135 can be formed by implanting an n-type dopant in the upper surface of the epitaxial layer 110 and then driving-in the dopant using any known process. The resulting structures after forming the contact region 135 are illustrated in FIGS. 5a and 5b.

Then, the upper surface of the gate is covered with an overlying insulating layer. The overlying insulating layer can be any insulating material known in the art. In some embodiments, the overlying insulating layer comprises any dielectric material containing B and/or P, including BPSG, PSG, or BSG materials. In some embodiments, the overlying insulating layer may be deposited using any CVD process until the desired thickness is obtained. Examples of the CVD processes include PECVD, APCVD, SACVD, LPCVD, HDPCVD, or combinations thereof. When BPSG, PSG, or BSG materials are used in the overlying insulating layer, they can be reflowed.

Then a portion of the overlying insulating layer is removed to leave an insulation cap. In the embodiments depicted in FIG. 5b, the overlying insulating layer can be removed using any known mask and etching procedure that removes the materials in locations other than the gate 155. Thus, an insulating cap 165 is formed over the gate 150. In the embodiments depicted in FIG. 5a, the insulating layer can be removed using any etch back or planarization process so that an oxide cap 160 is formed with an upper surface substantially co-planar with the contact region 135.

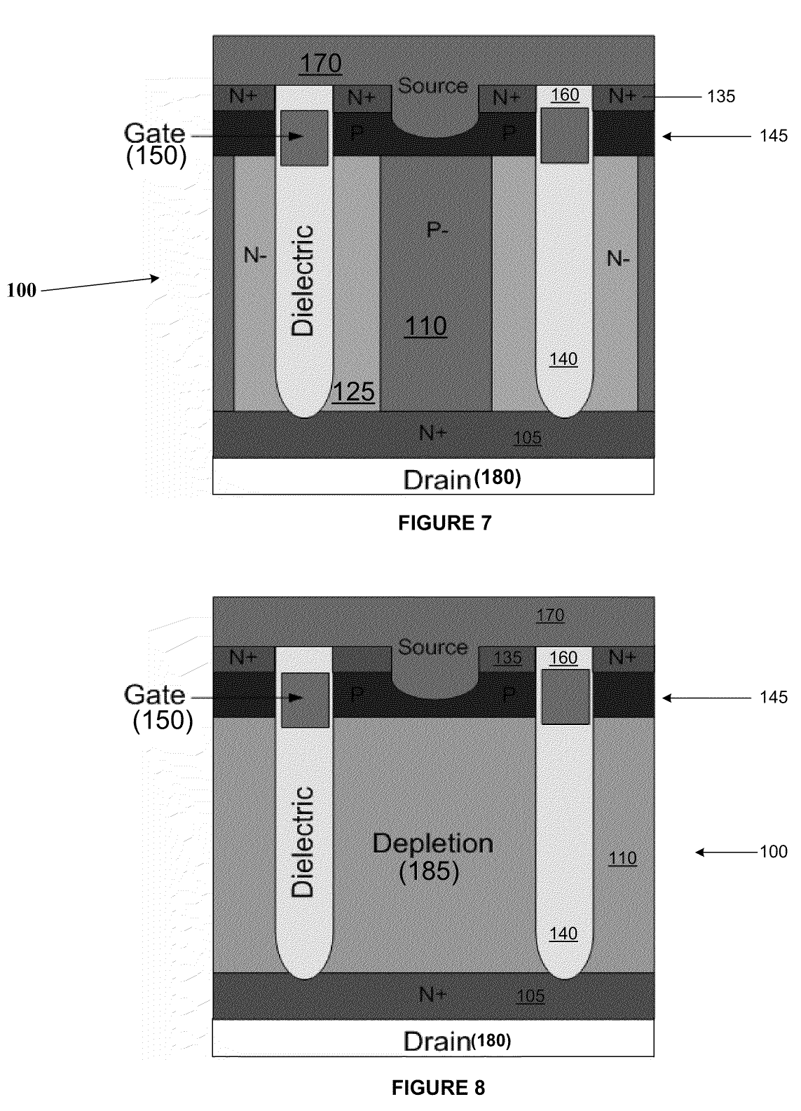

Next, as depicted in FIG. 6, the contact region 135 and the p-region 145 can be etched to form an insert region 167. FIG. 6 (and FIGS. 7-8) illustrates those embodiments containing gate 150 and insulating cap 160, but similar processes could be used to manufacture a similar semiconductor device containing gate 155 and insulating cap 165. The insert region 167 can be formed using any known masking and etching process until the desired depth (into the p-region 145) is reached. If desired, a heavy body implant can be performed using a p-type dopant to form a PNP region, as known in the art.

Next, as shown in FIG. 6, a source layer (or region) 170 can be deposited over the upper portions of the insulation cap 160 and the contact region 135. The source layer 170 can comprise any conductive and/or semiconductive material known in the art, including any metal, silicide, polysilicon, or combinations thereof. The source layer 170 can be deposited by any known deposition process, including chemical vapor deposition processes (CVD, PECVD, LPCVD) or sputtering processes using the desired metal as the sputtering target. The source layer 160 will also fill in the insert region 167.

After (or before) the source layer 170 has been formed, a drain 180 can be formed on the backside of the substrate 105 using any process known in the art. In some embodiments, the drain 180 can be formed on the backside by thinning the backside of the substrate 105 using any process known in the art, including a grinding, polishing, or etch processes. Then, a conductive layer can be deposited on the backside of the substrate 105 as known in the art until the desired thickness of the conductive layer of the drain is formed, as shown in FIG. 6.

These methods of manufacturing have several useful features. Using these methods, it can be easier to use a self-alignment method for making the contact insert region 167 (as depicted in FIGS. 5a and 6). As well, the superjunction structure can be made at a lower cost compared to conventional process such as long selective epitaxial growth.

One example of the semiconductor devices 100 resulting from these methods (which contain gate 150 and insulating cap 160) is depicted in FIGS. 7 and 8. In FIG. 7, the semiconductor device 100 contains a source layer 170 that is located in an upper portion of the device 100 and a drain 180 located in the bottom portion of the device. The gate 150 of the trench MOSFET is isolated between the bottom oxide region 140 and the insulating cap 160. At the same time, the gate 150 is also insulated from the n-type sidewall dopant regions 125 which, along with the p-type epitaxial layer 110, form the PN junction of a super-junction structure. With such a configuration, the gate 150 of the MOSFET can be used to control the current path in the semiconductor device 100.

The operation of the semiconductor device 100 is similar to other MOSFET devices. For example, like a MOSFET device, the semiconductor device operates normally in an off-state with the gate voltage equal to 0. When a reverse bias is applied to the source and drain with gate voltage below the threshold voltage, the depletion region 185 can expand and pinch off the drift region, as shown in FIG. 8.

The semiconductor devices 100 have an architecture with several features. First, the semiconductor device can achieve high breakdown voltage (≧ about 200V) without a long epitaxial growth process that has a high cost. Second, it can have a lower capacitance which, when combined with the higher breakdown voltage, can replace shield-based MOSFET devices in medium voltage ranges (about 200V) operations. And relative to shield-based MOSFET devices, the devices described herein can be manufactured less expensively due to reduced process steps and with a lower thermal budget because there they contain no shield oxide or shield polysilicon structures. Third, relative to planar architectures, the devices described herein require less area and are more suitable to a self-alignment scheme.

The semiconductor devices 100 also can have less defect related issues relative to other devices. With the devices described herein, the direction of the electric field is close to vertical within the thick bottom oxide (TBO) region once the depletion region 185 is formed. And even if some defect is formed in the TBO region, the devices still have very high oxide thickness (along the vertical length) to sustain the voltage. Thus, the devices described herein can also have a lower leakage current risk.

And combining the MOSFET structures in a trench with a super-junction structure can increase the drift doping concentration and can also define a smaller pitch that is able to improve both the current conductivity and the frequency (the switching speed). And due to the super-junction created made by junction of the N trench sidewall and the P epitaxial layer, the drift region doping concentration can be much higher than other MOSFET structures.

It is understood that all material types provided herein are for illustrative purposes only. Accordingly, one or more of the various dielectric layers in the embodiments described herein may comprise low-k or high-k dielectric materials. As well, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

In some embodiments, a method for making a semiconductor device comprises providing a semiconductor substrate heavily doped with a dopant of a first conductivity type, providing an epitaxial layer on the substrate, the epitaxial layer being lightly doped with a dopant of a second conductivity type with a concentration gradient, providing a trench formed in the epitaxial layer, the trench containing a MOSFET structure without a shield electrode and also containing a sidewall that is lightly doped with a dopant of a first conductivity type, providing a source layer contacting an upper surface of the epitaxial layer and an upper surface of the MOSFET structure, and providing a drain contacting a bottom portion of the substrate.

In some embodiments, a method for making a semiconductor device comprises providing a semiconductor substrate heavily doped with a dopant of a first conductivity type, depositing an epitaxial layer on the substrate, the epitaxial layer being lightly doped with a dopant of a second conductivity type and containing a decreasing dopant concentration as it approaches the substrate, forming a trench in the epitaxial layer, the trench containing a sidewall angle ranging from about 90 (vertical side wall) to about 70 degrees, forming a dopant region in the trench sidewall using an angled implantation process, the dopant region being lightly doped with a dopant of the first conductivity type, forming a first insulating region in a lower portion of the trench, forming a gate insulating layer in the upper portions of the trench, forming a conductive gate on the first insulating region and between the gate insulating layer, forming a second insulating region on the conductive gate, forming a contact region on the upper surface of the epitaxial layer, the contact region being heavily doped with a dopant of a first conductivity type, depositing a source on the upper surface of the contact layer and the upper surface of the second insulating region, and forming a drain on a bottom portion of the substrate.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor device, comprising:
a semiconductor substrate heavily doped with a dopant of a first conductivity type;
an epitaxial layer on the substrate, the epitaxial layer being lightly doped with a dopant of a second conductivity type;
a trench formed in the epitaxial layer, the trench containing a MOSFET structure without a shield electrode and also containing a sidewall that is lightly doped with a dopant of a first conductivity type;
a source layer contacting an upper surface of the epitaxial layer and an upper surface of the MOSFET structure; and
a drain contacting a bottom portion of the substrate.

2. The device of claim 1, wherein the first conductivity type dopant is an n-type dopant and the second conductivity type dopant is a p-type dopant.

3. The device of claim 1, wherein the epitaxial layer contains a concentration gradient that has a higher concentration at an upper surface and a lower concentration near the substrate.

4. The device of claim 3, wherein the concentration gradient decreases from the upper surface to the substrate in a substantially uniform or substantially step-wise manner.

5. The device of claim 1, wherein the MOSFET structure comprises a gate vertically insulated within the trench by deposited insulating materials.

6. The device of claim 5, wherein the gate is insulated from the epitaxial layer by a gate insulating layer.

7. The device of claim 1, wherein the trench comprises a sidewall with an angle range from about 90 to about 70 degrees.

8. The device of claim 1, wherein the trench sidewall dopant has been implanted at an angle ranging from more than 0, which is perpendicular to the surface of the substrate, to about 40 degrees.

9. A semiconductor device, comprising:
a semiconductor substrate heavily doped with a dopant of a first conductivity type;
an epitaxial layer on the substrate, the epitaxial layer being lightly doped with a dopant of a second conductivity type;
a trench formed in the epitaxial layer, the trench containing a sidewall that is lightly doped with a dopant of a first conductivity type, a gate vertically insulated within the trench by a bottom oxide region and an insulation cap and herein the gate is insulated from the epitaxial layer by a gate insulating layer;
a source layer contacting an upper surface of the epitaxial layer and an upper surface of the insulation cap; and
a drain contacting a bottom portion of the substrate.

10. The device of claim 9, wherein the first conductivity type dopant is an n-type dopant and the second conductivity type dopant is a p-type dopant.

11. The device of claim 9, wherein epitaxial layer contains a concentration gradient with a higher concentration at an upper surface and a lower concentration near the substrate.

12. The device of claim 11, wherein the concentration gradient decreases from the upper surface to the substrate in a substantially uniform or substantially step-wise manner.

13. The device of claim 9, wherein the trench comprises a sidewall with an angle range from about 90 to about 70 degrees.

14. The device of claim 9, wherein the trench sidewall dopant has been implanted at an angle ranging from more than 0 to about 40 degrees.

15. An electronic apparatus containing a semiconductor device, comprising:
a semiconductor substrate heavily doped with a dopant of a first conductivity type;
an epitaxial layer on the substrate, the epitaxial layer being lightly doped with a dopant of a second conductivity type;
a trench formed in the epitaxial layer, the trench containing a sidewall that is lightly doped with a dopant of a first conductivity type, a gate vertically insulated within the trench by a bottom oxide region and an insulation cap and herein the gate is insulated from the epitaxial layer by a gate insulating layer;
a source layer contacting an upper surface of the epitaxial layer and an upper surface of the insulation cap; and
a drain contacting a bottom portion of the substrate.

16. The apparatus of claim 15, wherein the first conductivity type dopant is an n-type dopant and the second conductivity type dopant is a p-type dopant.

17. The apparatus of claim 15, wherein the epitaxial layer contains a concentration gradient with a higher concentration at an upper surface and a lower concentration near the substrate.

18. The apparatus of claim 17, wherein the concentration gradient decreases from the upper surface to the substrate in a substantially uniform or substantially step-wise manner.

19. The apparatus of claim 15, wherein the trench comprises a sidewall with an angle range from about 90 to about 70 degrees.

20. The apparatus of claim 15, wherein the trench sidewall dopant has been implanted at an angle ranging from more than 0 to about 40 degrees.

21. The apparatus of claim 15, further comprising another epitaxial layer doped with a first conductivity type located between the substrate and the epitaxial layer.
